(19) United States
(12) Patent Application Publication
(10) Pub. No.: US 2025/0230542 A1
(43) Pub. Date: Jul. 17, 2025

(54) SUBSTRATE PROCESSING APPARATUS, METHOD OF MANUFACTURING SEMICONDUCTOR DEVICE, AND RECORDING MEDIUM

(71) Applicant: Kokusai Electric Corporation, Tokyo (JP)

(72) Inventor: Hideharu ITATANI, Toyama-shi (JP)

(73) Assignee: Kokusai Electric Corporation, Tokyo (JP)

(21) Appl. No.: 19/097,152

(22) Filed: Apr. 1, 2025

Related U.S. Application Data
(63) Continuation of application No. PCT/JP2023/034638, filed on Oct. 4, 2023.

(51) Int. Cl. C23C 16/44; C23C 16/52

(52) U.S. Cl. CPC C23C 16/4405; C23C 16/52

(57) ABSTRACT

A technique including: a plurality of substrate supports for supporting at least one substrate; a processing container in which the supports and the substrate are processed; a gas supplier for supplying a film forming gas for depositing a film and a cleaning gas removing the deposited film into the processing container; a memory that stores the thickness of the deposited film; and a controller for controlling the cleaning process of the processing container and the two or more of the plurality of substrate supports, wherein the cleaning process is performed where value of the processing container is greater than or equal to a threshold value and, wherein the cleaning process including: allocating a cleaning time for each of the plurality of substrate supports; taking the substrate supports into the processing container; supplying the cleaning gas to remove the deposited film; and, taking the substrate supports from the processing container.

### CROSS-REFERENCE TO RELATED APPLICATION

This application is a Bypass Continuation Application of PCT International Application No. PCT/JP2023/036228, filed on Oct. 4, 2023, the entire contents of which are incorporated herein by reference.

### BACKGROUND

### Field

The present disclosure relates to a substrate processing apparatus, a method of manufacturing a semiconductor device, and a recording medium.

### Description of the Related Art

As a substrate processing apparatus that performs processing of a substrate, there is a substrate processing apparatus including a processing container and a substrate holder (also referred to as a substrate support) that holds the substrate in multiple stages, in which a film-forming processing of the substrate in a state where the substrate holder is inserted into the processing container. In such a substrate processing apparatus, when the film-forming processing of the substrate is repeatedly performed, a film may be accumulated in the processing container or the substrate holder. In this case, cleaning to remove the accumulated film may be performed on both the processing container and the substrate holder.

### SUMMARY

The present disclosure provides a cleaning technique for efficiently removing a film accumulated in each of one processing container and a plurality of substrate supports.

According to one aspect of the present disclosure, there is provided a technique including:
a plurality of substrate supports capable of supporting at least one substrate;
a processing container in which the plurality of substrate supports is individually loaded and the substrate supported by the substrate supports is processed;
a gas supplier configured to supply a film forming gas for depositing a film and a cleaning gas removing the deposited film into the processing container;
a memory that stores a cumulative value of a thickness of the deposited film of each of the processing container and two or more the plurality of substrate supports; and
a controller configured to control the gas supplier to perform a cleaning process of the processing container and the two or more of the plurality of substrate supports,
   wherein the cleaning process is performed in a case where the cumulative value of the processing container is greater than or equal to a threshold value defined in advance and,
   wherein the cleaning process including:
      allocating a cleaning time of the processing container defined in advance for each of the two or more of the plurality of substrate supports on the basis of the cumulative values of each of the plurality of substrate supports;
      taking each of the two or more of the plurality of substrate supports into the processing container;
      supplying the cleaning gas to remove the deposited film in accordance with cleaning times allocated for each of the two or more of the plurality of substrate supports; and,
      taking each of the two or more of the plurality of substrate supports from the processing container.

### BRIEF DESCRIPTION OF THE DRAWINGS

FIG. 1 is an overall perspective view of a substrate processing apparatus.

FIG. 2 is a horizontal cross-sectional view of the substrate processing apparatus.

FIG. 3 is a longitudinal sectional view of a processing furnace of the substrate processing apparatus.

FIG. 4 is a block diagram illustrating a controller section of the substrate processing apparatus.

FIG. 5 is a flowchart of film thickness monitoring processing.

FIG. 6 is a partial flowchart of processing by a main controller after receiving a cleaning signal.

FIG. 7 is a flowchart of cleaning time allocation processing.

FIG. 8 is a table of a specific example of cleaning time allocation.

FIG. 9 is a flowchart of cleaning processing.

FIGS. 10A to 10C are explanatory diagrams illustrating positions of boats in the cleaning processing, in which FIG. 10A illustrates a state where a first boat is disposed in a process chamber, FIG. 10B illustrates a state where a second boat is disposed in the process chamber, and FIG. 10C illustrates a state where a third boat is disposed in the process chamber.

### DETAILED DESCRIPTION

Hereinafter, the present embodiment will be described with reference to the drawings. The drawings used in the following description are all schematic, and dimensional relationships between elements, ratios between elements, and the like illustrated in the drawings do not necessarily coincide with actual ones. In addition, dimensional relationships between elements, ratios between elements, and the like do not necessarily coincide with each other between a plurality of drawings. In addition, a processing temperature in the present description means a temperature of a substrate (wafer 7) or a temperature in a process chamber (a process chamber 101).

### Configuration of Substrate Processing Apparatus

A substrate processing apparatus 1 according to the present embodiment executes a substrate processing process based on a recipe in which a processing procedure and a processing condition are defined to perform processing on a substrate, and is configured as a vertical batch-type substrate processing apparatus that simultaneously performs processing on a plurality of substrates.

Examples of the substrate to be processed include a semiconductor wafer substrate (hereinafter, simply referred to as “wafer”) on which a semiconductor integrated circuit device (semiconductor device (device)) is built. In addition, as a typical example, the processing performed by the substrate processing apparatus includes film-forming processing such as processing of forming a thin film on the surface of the wafer.

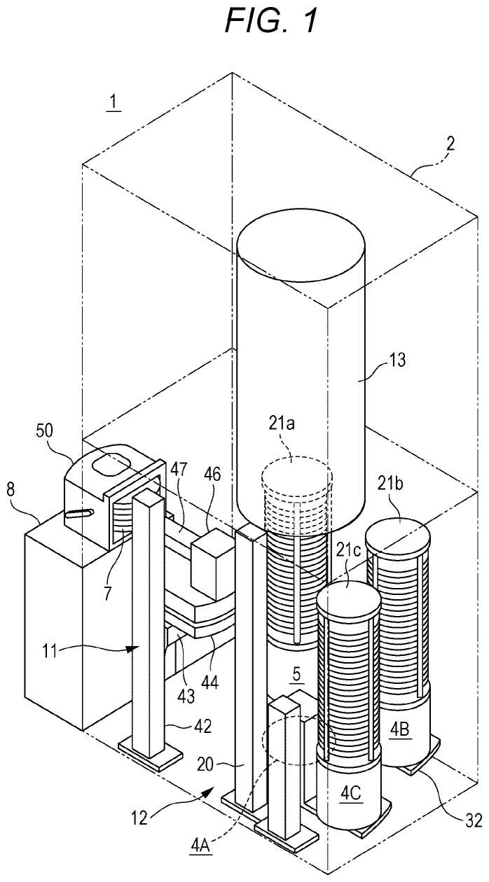

FIG. 1 is an overall perspective view of the substrate processing apparatus 1 for performing a method of manufacturing a device. The substrate processing apparatus 1 includes a housing 2 configured as a pressure-resistant container. A transfer stage 8 for transferring a pod 50, which is a substrate storing container, is provided on the front (diagonally back left in FIG. 1) of the housing 2.

The pod 50 is a sealed transfer container that is transferred in a state where a predetermined number of wafers 7 to be processed are stored, and includes an openable and closable lid. Specifically, for example, a front opening unified pod (FOUP) is used as the pod 50.

The transfer stage 8 is for transferring the pod 50 between the substrate processing apparatus 1 and the outside, and includes a door opening and closing device (not illustrated) for opening and closing the lid (not illustrated) of the pod 50. In addition, a wafer loading/unloading port (not illustrated) is opened on the front wall of the housing 2 corresponding to the transfer stage 8 so that the inside and the outside of the housing 2 communicate with each other.

In the housing 2, roughly divided, a wafer transfer section 11, a boat transfer section 12, and a processing furnace 13 are disposed. A configuration of the processing furnace 13 will be described later.

### Wafer Transfer Section

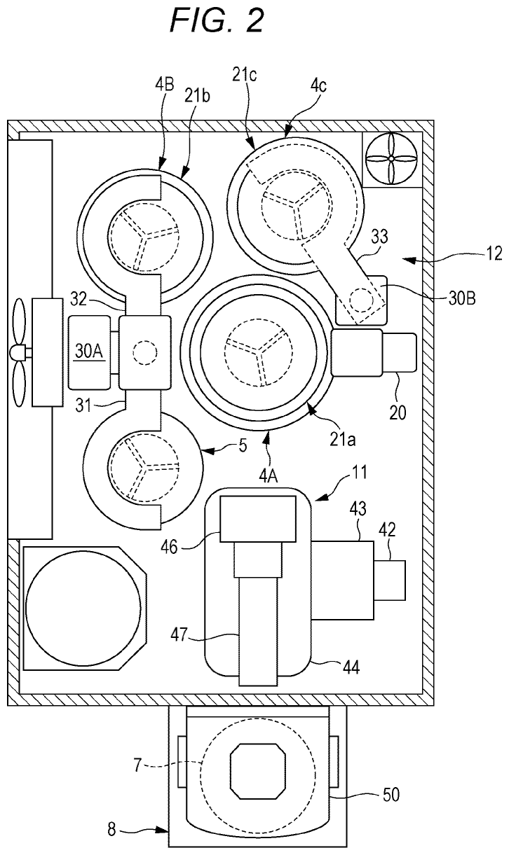

As illustrated in FIG. 1 or 2, the wafer transfer section 11 is disposed so as to face the transfer stage 8 with the wafer loading/unloading port interposed therebetween, and is configured to transfer the wafers 7 between the pod 50 on the transfer stage 8 and a boat 21 serving as a substrate holder supported by a boat transfer section 12 described later. More specifically, the wafer transfer section 11 includes an elevator 42 including a raising/lowering mechanism, a raising/lowering base 43 raised or lowered by the elevator 42, a rotary table 44 rotatably provided on the raising/lowering base 43, and a wafer transfer head 46 provided on the rotary table 44 so as to be movable forward and backward. The wafer transfer head 46 is provided with a predetermined number of wafer transfer plates 47 for holding the wafers 7 in the up-down direction. Then, the wafer transfer section 11 is configured to be capable of loading and unloading the wafers 7 to and from the boat 21 in cooperation of raising/lowering, rotation, and moving forward and backward.

The wafer transfer section 11 is electrically connected to a machine controller 205 in a controller section 200 described later, and is configured so that operations such as raising/lowering, rotation, moving forward and backward are controlled in accordance with an instruction from the machine controller 205.

### Boat Transfer Section

As illustrated in FIG. 1 or 2, the boat transfer section 12 is disposed in a rear region of the wafer transfer section 11 (the back side when viewed from the front of the housing 2), and includes four stages 4A, 4B, 4C, and 5 that support the boat 21, and is configured to transfer the boat 21 between the stages 4A, 4B, 4C, and 5.

The boat 21 is configured to horizontally hold a plurality of (for example, about 50 or more and 200 or less) wafers 7 in a state where the centers thereof are aligned in the vertical direction. The boat 21 includes a heat-resistant material, for example, quartz (SiO₂), silicon carbide (SiC), or the like.

As the four stages 4A, 4B, 4C, and 5, there are a transfer position (hereinafter, abbreviated as “TR”) stage 5 that is closest to the wafer transfer section 11 and at which the wafer 7 is loaded or unloaded by the wafer transfer section 11; escape position (hereinafter, abbreviated as “ES”) stages 4B and 4C located at positions away from the wafer transfer section 11; and a boat load position (hereinafter, abbreviated as “BL”) stage 4A located between these and immediately below the processing furnace 13.

The boat transfer section 12 includes a boat elevator 20 provided corresponding to the BL stage 4A. The boat elevator 20 is configured to load the boat 21 into the processing furnace 13 from the position of the BL stage 4A and unload the boat 21 from the processing furnace 13 to the position of the BL stage 4A.

Furthermore, as illustrated in FIG. 2, the boat transfer section 12 includes boat transfer mechanisms 30A and 30B provided at positions facing each other with the boat elevator 20 and the BL stage 4A interposed therebetween. The boat transfer mechanisms 30A and 30B are configured to transfer the boat 21 between the TR stage 5, the BL stage 4A, and the ES stages 4B and 4C. The boat transfer mechanism 30A includes an upper arm 32 and a lower arm 31. The boat transfer mechanism 30B includes an arm 33. The upper arm 32, the lower arm 31, and the arm 33 are all formed in an arc shape so as to be fittable to predetermined positions of the boat 21.

The boat transfer section 12 is configured so that the boat elevator 20, the boat transfer mechanisms 30A and 30B, and the like are electrically connected to the machine controller 205 in the controller section 200 described later, and operations such as raising/lowering and transferring the boat 21 are controlled in accordance with an instruction from the machine controller 205.

### Process Chamber

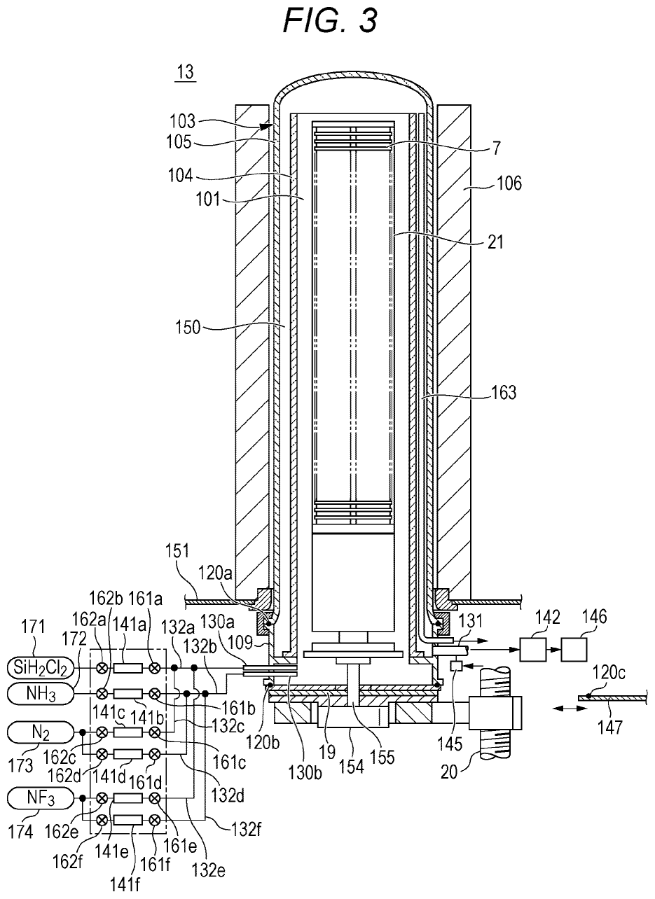

As illustrated in FIG. 3, the processing furnace 13 includes a process tube 103. The process tube 103 includes an inner tube 104 and an outer tube 105 provided outside the inner tube 104. The inner tube 104 includes a heat-resistant material, for example, quartz (SiO₂), silicon carbide (SiC), or the like. The inner tube 104 is formed in a cylindrical shape with the upper end and the lower end opened. The process chamber 101 for processing the wafer 7 serving as a substrate is formed in a cylindrical hollow portion in the inner tube 104. For that reason, the inner tube 104 is configured so that the boat 21 is loaded and the loaded boat 21 can be accommodated. The outer tube 105 is provided concentrically with the inner tube 104. The outer tube 105 has an inner diameter larger than an outer diameter of the inner tube 104, and is formed in a cylindrical shape with the upper end closed and the lower end opened. The outer tube 105 includes a heat-resistant material, for example, SiO₂, SiC, or the like.

### Heater

A heater 106 is provided outside the process tube 103 so as to surround a side wall surface of the process tube 103. The heater 106 is configured to generate heat by supply of electric power to a heater wire, and is vertically installed by being supported by a heater base 151. A temperature sensor 163 is installed between the inner tube 104 and the outer tube 105. The heater 106 and the temperature sensor 163 are electrically connected to a temperature controller 202 in the controller section 200 described later.

### Manifold

Below the outer tube 105, a manifold 109 is disposed so as to be concentrically with the outer tube 105. The manifold 109 includes, for example, stainless steel (SUS) or the like, and is formed in a cylindrical shape with the upper end and the lower end opened. The manifold 109 is engaged with a lower end portion of the inner tube 104 and a lower end portion of the outer tube 105, and is provided to support them. Between the manifold 109 and the outer tube 105, an O-ring 120a serving as a seal member is provided. Although not illustrated, the manifold 109 is supported by the heater base 151, so that the process tube 103 is vertically installed. The process tube 103 and the manifold 109 form a processing container.

### First Gas Supply System

The manifold 109 is provided with a nozzle 130a for supplying a silicon-containing gas serving as a first gas into the process chamber 101 so as to communicate with the process chamber 101. The downstream end of a gas supply pipe 132a is connected to the upstream end of the nozzle 130a. The gas supply pipe 132a is provided with a first gas supply source 171, a valve 162a, a mass flow controller (MFC) 141a, and a valve 161a in this order from the upstream side. Mainly the nozzle 130a, the gas supply pipe 132a, the MFC 141a, and the valves 161a and 162a constitute a first gas supply system. The first gas supply source 171 may be included in the first gas supply system. The MFC 141a and the valves 161a and 162a are electrically connected to a gas flow rate controller 204 in the controller section 200 described later.

### Second Gas Supply System

The manifold 109 is provided with a nozzle 130b for supplying a nitrogen-containing gas serving as a second gas into the process chamber 101 so as to communicate with the process chamber 101. The downstream end of a gas supply pipe 132b is connected to the upstream end of the nozzle 130b. The gas supply pipe 132b is provided with a second gas supply source 172, a valve 162b, an MFC 141b, and a valve 161b in this order from the upstream side. Mainly the nozzle 130b, the gas supply pipe 132b, the MFC 141b, and the valves 161b and 162b constitute a second gas supply system. The second gas supply source 172 may be included in the second gas supply system. The MFC 141b and the valves 161b and 162b are electrically connected to the gas flow rate controller 204 in the controller section 200 described later.

### Third Gas (Cleaning Gas) Supply System

A gas supply pipe 132e for supplying, for example, a fluorine (F)-containing gas as a cleaning gas serving as a third gas into the process chamber 101 is connected to the downstream side of the valve 161a of the gas supply pipe 132a. As the F-containing gas, it is possible to use, for example, chlorine trifluoride (CIF₃) gas, chlorine fluoride (CIF) gas, nitrogen trifluoride (NF₃) gas, hydrogen fluoride (HF) gas, fluorine (F₂) gas, or the like. One or more of them can be used as the F-containing gas. The gas supply pipe 132e is provided with a third gas supply source 174, a valve 162e, an MFC 141e, and a valve 161e in this order from the upstream side.

A gas supply pipe 132f for supplying the third gas into the process chamber 101 is connected to the downstream side of the valve 161b of the gas supply pipe 132b. The upstream end of the gas supply pipe 132f is connected to the upstream side of the valve 162e of the gas supply pipe 132e. The gas supply pipe 132f is provided with a valve 162f, an MFC 141f, and a valve 161f in this order from the upstream side.

Mainly the nozzles 130a and 130b, the gas supply pipes 132a, 132b, 132e, and 132f, the MFCs 141e and 242f, the valves 161e, 161f, 162e, and 162f constitute a third gas supply system. The third gas supply source 174 may be included in the third gas supply system.

The MFCs 141e and 141f and the valves 161e, 161f, 162e, and 162f are electrically connected to the gas flow rate controller 204 in the controller section 200 described later.

### Fourth Gas (Inert Gas) Supply System

A gas supply pipe 132c for supplying nitrogen (N₂) gas as an inert gas serving as a fourth gas into the process chamber 101 is connected to the downstream side of the valve 161a of the gas supply pipe 132a. The gas supply pipe 132c is provided with a fourth gas supply source 173, a valve 162c, an MFC 141c, and a valve 161c in this order from the upstream side.

A gas supply pipe 132d for supplying the fourth gas into the process chamber 101 is connected to the downstream side of the valve 161b of the gas supply pipe 132b. The upstream end of the gas supply pipe 132d is connected to the upstream side of the valve 162c of the gas supply pipe 132c. The gas supply pipe 132d is provided with a valve 162d, an MFC 141d, and a valve 161d in this order from the upstream side.

Mainly the nozzles 130a and 130b, the gas supply pipes 132a, 132b, 132c, and 132d, the MFCs 141c and 141d, and the valves 161c, 161d, 162c, and 162d constitute a fourth gas supply system. The fourth gas supply source 173 may be included in the fourth gas supply system.

The MFCs 141c and 141d and the valves 161c, 161d, 162c, and 162d are electrically connected to the gas flow rate controller 204 in the controller section 200 described later. Mainly at least one or more of the first gas supply system, the second gas supply system, the third gas supply system, and the fourth gas supply system constitutes a gas supply system of the present disclosure.

### Exhaust System

The manifold 109 is provided with an exhaust pipe 131 for exhausting the atmosphere in the process chamber 101. The exhaust pipe 131 is disposed at the lower end portion of a cylindrical space 150 formed by a gap between the inner tube 104 and the outer tube 105, and communicates with the cylindrical space 150. On the downstream side of the exhaust pipe 131 (an opposite side from a connection side with the manifold 109), a vacuum exhaust device 146 such as a vacuum pump is provided through a pressure sensor 145 and a pressure regulation device 142 such as a variable conductance valve, for example, an auto pressure controller (APC) valve. The vacuum exhaust device 146 is configured to perform exhaust so that a pressure in the process chamber 101 reaches a predetermined pressure (degree of vacuum). The pressure regulation device 142 and the pressure sensor 145 are electrically connected to a pressure controller 203 in the controller section 200 described later.

With the above-described configuration, the first gas, the second gas, the third gas, and the fourth gas each ascend in the inner tube 104 (in the process chamber 101), flow out from the upper end opening of the inner tube 104 into the cylindrical space 150, flow down in the cylindrical space 150, and then are exhausted from the exhaust pipe 131. Mainly the exhaust pipe 131 and the pressure regulation device 142 constitute an exhaust system according to the present embodiment. The vacuum exhaust device 146 may be included in the exhaust system.

### Seal Cap

A lower portion of the manifold 109 is airtightly closed by a seal cap 19 included in the boat elevator 20 of the boat transfer section 12. That is, the seal cap 19 functions as a furnace lid capable of airtightly closing the lower end opening of the manifold 109, and is brought into contact with the lower end of the manifold 109 from the lower side in the vertical direction. The seal cap 19 is made of metal, for example, stainless steel, and is formed into a disk shape. On the upper surface of the seal cap 19, an O-ring 120b is provided serving as a seal member that is in contact with the lower end of the manifold 109.

### Rotation Mechanism

Near the central portion of the seal cap 19 and on the opposite side from the process chamber 101, a rotation mechanism 154 for rotating the boat 21 is installed. A rotation shaft 155 of the rotation mechanism 154 penetrates the seal cap 19 and supports the boat 21 from below. The rotation mechanism 154 is configured to be capable of rotating the boat 21.

### Boat Elevator

The seal cap 19 is raised and lowered in the vertical direction by the boat elevator 20 vertically installed outside the process tube 103. By raising and lowering the seal cap 19, it is possible to transfer the boat 21 into and out of the process chamber 101. The rotation mechanism 154 and the boat elevator 20 are electrically connected to the machine controller 205 in the controller section 200 described later.

### Shutter

Below the manifold 109, a furnace shutter 147 is provided serving as a second furnace lid capable of airtightly closing the lower end opening of the manifold 109. The furnace shutter 147 is brought into contact with the lower end of the manifold 109 after the boat 21 is unloaded from the process chamber 101 by raising/lowering and rotation, and airtightly closes the process chamber 101 after the boat 21 is unloaded. On the upper surface of the furnace shutter 147, an O-ring 120c is provided serving as a seal member that is in contact with the lower end of the manifold 109

### Configuration of Controller Section

In the substrate processing apparatus 1 configured as described above, processing operation thereof is controlled by an instruction from the controller section 200 serving as a controller. The controller section 200 may be disposed in the housing 2 of the substrate processing apparatus 1, or may be installed separately from the housing 2 of the substrate processing apparatus 1 and electrically connected through a communication line or the like.

Hereinafter, a configuration of the controller section 200 according to the present embodiment will be described with reference to the drawings.

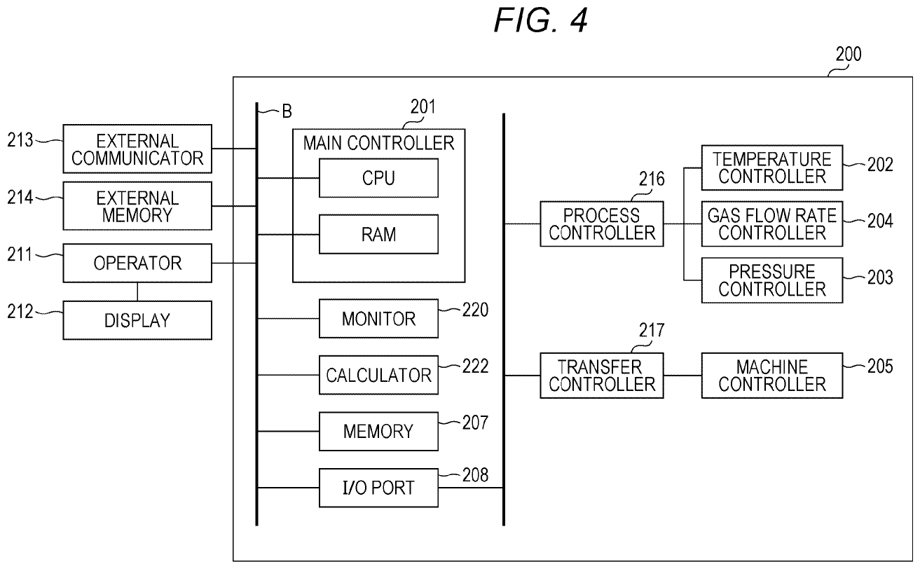

As illustrated in FIG. 4, the controller section 200 includes a main controller 201 and a plurality of controllers, each of which is constructed by a computer. The computer herein executes a program to perform information processing that the computer is instructed by the program, and specifically includes a combination of a central processing unit (CPU), a random access memory (RAM), a memory, an input/output device, and the like. The plurality of controllers includes the temperature controller 202, the pressure controller 203, the gas flow rate controller 204, and the machine controller 205. The temperature controller 202, the pressure controller 203, and the gas flow rate controller 204 are connected to a process controller 216, and the machine controller 205 is connected to a transfer controller 217. The process controller 216 and the transfer controller 217 are connected to an I/O port 208 through a communication line, and are connected to the main controller 201 through a bus B.

The temperature controller 202 is configured to control a degree of energization to the heater 106 at a desired timing on the basis of temperature information detected by the temperature sensor 163 so that the temperature in the process chamber 101 has a desired temperature distribution.

The pressure controller 203 is configured to control the pressure regulation device 142 at a desired timing on the basis of pressure information detected by the pressure sensor 145 so that the pressure in the process chamber 101 reaches a desired pressure.

The gas flow rate controller 204 is configured to control a flow rate of a gas supplied into the process chamber 101. More specifically, the MFC 141a and the valves 161a and 162a are controlled so that a flow rate of the silicon-containing gas supplied into the process chamber 101 reaches a predetermined flow rate at a predetermined timing. The MFC 141b and the valves 161b and 162b are controlled so that a flow rate of the nitrogen-containing gas supplied into the process chamber 101 reaches a predetermined flow rate at a predetermined timing. The MFCs 141e and 141f and the valves 161e, 161f, 162e, and 162f are controlled so that a flow rate of the cleaning gas supplied into the process chamber 101 reaches a predetermined flow rate at a predetermined timing. The MFCs 141c and 141d and the valves 161c, 161d, 162c, and 162d are controlled so that a flow rate of the inert gas supplied into the process chamber 101 reaches a predetermined flow rate at a predetermined timing.

The machine controller 205 is configured to perform control at a desired timing so that the wafer transfer section 11, the boat transfer mechanism 30, the boat elevator 20, the rotation mechanism 154, and the like perform desired operations.

The main controller 201 is configured to perform overall operation control of the substrate processing apparatus 1 by controlling the temperature controller 202, the pressure controller 203, and the gas flow rate controller 204 through the process controller 216, and controlling the machine controller 205 through the transfer controller 217.

The main controller 201 is connected to an operator 211 configured as, for example, a touch panel or the like, a display 212 such as a display device, an external communicator 213 for performing communication with the outside, and an external memory 214 that is a memory provided outside, in addition to the above-described controllers.

The controller section 200 includes a memory 207. The memory 207 includes a memory device such as a hard disk device, and is configured to store various programs, recipes, and the like for performing the operation of the substrate processing apparatus 1. The recipes stored in the memory 207 include a maintenance recipe for cleaning the inside of the process chamber 101 in addition to recipes in which processing procedures and processing conditions of the substrate processing process are defined. For example, a gas cleaning recipe, a purge cleaning recipe, or the like is stored in the memory 207 as the maintenance recipe. The memory 207 is connected to the main controller 201 through the bus B.

The controller section 200 includes a monitor 220 and a calculator 222. Both the monitor 220 and the calculator 222 are constructed by the computer, and execute a program to perform information processing that the computer is instructed by the program. As will be described later, the monitor 220 has a function of monitoring a cumulative film thickness A0 of the process chamber 101, and executes film thickness monitoring processing. As will be described later, the calculator 222 has a function of allocating the cleaning times for a first boat 21a, a second boat 21b, and a third boat 21c that are a plurality of the boats 21 in accordance with cumulative values of the film thickness of the respective boats 21, and executes cleaning time allocation processing of allocating the cleaning times.

It is possible to configure the controller 200 by installing the above-described program stored in the external memory 124 in the computer. Examples of the external memory 124 include, for example, a magnetic disk such as an HDD, an optical disk such as a CD, a magneto-optical disk such as an MO, a semiconductor memory such as a USB memory or an SSD. The memory 207 and the external memory 124 are configured as computer-readable recording media. Hereinafter, the memories are also collectively and simply referred to as a recording medium. In a case where the term “recording medium” is used in the present description, the term may include only the memory 207 alone, may include only the external memory 124 alone, or may include both of them. The program may be provided to the computer by use of a communication means such as the Internet or a dedicated line without use of the external memory 124.

### Substrate Processing Method

Next, a description will be given of a substrate processing method performed using the substrate processing apparatus 1. Here, as an example, a case will be described where a substrate processing step is performed that is one step of a semiconductor device manufacturing step. In performing the substrate processing step, as illustrated in FIG. 1, the substrate processing apparatus 1 includes three boats 21 (hereinafter, these are referred to as “first boat 21a”, “second boat 21b”, and “third boat 21c” for identification), ant it is assumed that the boats are placed on the TR stage 5 and the ES stages 4B and 4C, respectively.

In performing the substrate processing step, the controller section 200 first reads a recipe corresponding to the substrate processing to be performed from the memory 207 and deploys the recipe in the RAM in the main controller 201. Then, an operation instruction is given from the main controller 201 to each of the controllers 202, 203, 204, and 205 through the process controller 216 and the transfer controller 217. The substrate processing step performed in this manner roughly includes a transfer step, a loading step, a film-forming step, a boat transfer step, and an unloading step.

### Transfer Step

When the first boat 21a placed on the TR stage 5 is an empty boat, an instruction to drive the wafer transfer section 11 is issued from the main controller 201 to the machine controller 205. Then, in accordance with an instruction from the machine controller 205, the wafer transfer section 11 starts transfer processing of the wafers 7 from the pod 50 on the transfer stage 8 to the first boat 21a on the TR stage 5. This transfer processing is performed until scheduled loading of all the wafers 7 into the boat 21 is completed.

### Loading Step

When a designated number of wafers 7 are loaded into the first boat 21a in the TR stage 5, the first boat 21a is transferred from the TR stage 5 to the BL stage 4A by the lower arm 31 of the boat transfer mechanism 30 operating in accordance with an instruction from the machine controller 205, and is transferred onto the seal cap 19 in the boat elevator 20. After the transfer of the first boat 21a, the lower arm 31 returns to the TR stage 5.

Thereafter, the first boat 21a is raised by the boat elevator 20 operating in accordance with an instruction from the machine controller 205, and is loaded into the process chamber 101 formed in the inner tube 104 of the processing furnace 13. When the first boat 21a is completely loaded, the seal cap 19 of the boat elevator 20 airtightly closes the lower end of the manifold 109 of the processing furnace 13.

At this time, the inside of the process chamber 101 is purged by supply of N₂ gas in accordance with an instruction from the gas controller 204. That is, the N₂ gas supplied from the fourth gas supply source 173 into the gas supply pipes 132c and 132d by opening of the valves 162c, 161c, 162d, and 161d is controlled to have a predetermined flow rate by the MFCs 141c and 141d, and then supplied from the nozzles 130a and 130b into the process chamber 101 through the gas supply pipes 132a and 132b. The supply of the N₂ gas into the process chamber 101 is continued until all the steps of the substrate processing step are completed.

### Film-Forming Step

Thereafter, the inside of the process chamber 101 is vacuum-exhausted by the vacuum exhaust device 146 so as to have a predetermined film-forming pressure in accordance with an instruction from the pressure controller 203. In addition, the inside of the process chamber 101 is heated by the heater 106 to have a predetermined temperature in accordance with an instruction from the temperature controller 202. Subsequently, rotation of the first boat 21a by the rotation mechanism 154 is started in accordance with an instruction from the machine controller 205.

When the inside of the process chamber 101 is maintained at a predetermined film-forming temperature and a predetermined film-forming pressure, supply of, for example, a silicon-containing gas and, for example, a nitrogen-containing gas into the process chamber 101 is started in accordance with an instruction from the gas flow rate controller 204. That is, the first gas supplied from the first gas supply source 171 into the gas supply pipe 132a by opening of the valves 162a and 161a is controlled to have a predetermined flow rate by the MFC 141a, and then supplied from the nozzle 130a into the process chamber 101 through the gas supply pipe 132a. In addition, the second gas supplied from the second gas supply source 172 into the gas supply pipe 132b by opening of the valves 162b and 161b is controlled to have a predetermined flow rate by the MFC 141b, and then supplied from the nozzle 130b into the process chamber 101 through the gas supply pipe 132b.

At this time, the N₂ gas supplied into the process chamber 101 functions as a dilution gas for diluting a film-forming gas (the first gas and the second gas) or a carrier gas for promoting diffusion into the process chamber 101. By controlling the supply flow rate of the N₂ gas, it is possible to control a concentration and a diffusion rate of the film-forming gas.

The film-forming gas comes into contact with the surface of the wafer 7 when passing through the process chamber 101.

At this time, a thin film (hereinafter, also simply referred to as a film) is deposited on the wafer 7 by a thermal CVD reaction. When a processing time set in advance has elapsed and a film having a predetermined thickness is formed, the valves 162a, 161a, 162b, and 161b are closed, and the supply of the film-forming gas into the process chamber 101 is stopped. The processing time in the present description means a time during which the processing is continued. The same applies to the following description. Here, in a case where a silicon-containing gas is used as the first gas and a nitrogen-containing gas is used as the second gas, a silicon nitride film is formed on the wafer 7.

Then, the valves 162c, 161c, 162d, and 161d are kept open, and the inside of the process chamber 101 is purged by exhausting of the inside of the process chamber 101 while the supply of the N₂ gas into the process chamber 101 is continued. When the atmosphere in the process chamber 101 is replaced with the N₂ gas, a degree of opening of the pressure regulation device 142 is adjusted to return the pressure in the process chamber 101 to normal pressure. In addition, the energization to the heater 106 is stopped, and the temperature in the process chamber 101 is lowered to a predetermined temperature (wafer unloading temperature).

### Boat Transfer Step

During the film-forming step for the first boat 21a, the second boat 21b or the third boat 21c is transferred from the ES stage 4B or 4C onto the TR stage 5 by the boat transfer mechanism 30 in accordance with an instruction from the machine controller 205.

At this time, when the second boat 21b or the third boat 21c transferred to the TR stage 5 is an empty boat, the transfer step is performed on the second boat 21b or the third boat 21c. That is, the wafers 7 of the pod 50 on the transfer stage 8 are transferred to the second boat 21b or the third boat 21c on the TR stage 5 by the wafer transfer section 11. However, in a case where the processed wafers 7 are held in the second boat 21b or the third boat 21c, the processed wafers 7 are unloaded from the second boat 21b or the third boat 21c and transferred to the pod 50, and then a new unprocessed wafer 7 is transferred to the second boat 21b or the third boat 21c.

### Unloading Step

When the film-forming step for the first boat 21a is completed, the rotation of the first boat 21a by the rotation mechanism 154 is then stopped in accordance with an instruction from the machine controller 205, the seal cap 19 is lowered by the boat elevator 20 to open the lower end of the manifold 109, and the first boat 21a holding the processed wafers 7 is unloaded to the outside of the process tube 103.

Then, the first boat 21a holding the processed wafers 7 is immediately transferred from the BL stage 4A to the ES stage 4B or 4C by the boat transfer mechanism 30 in accordance with an instruction from the machine controller 205. After this transfer, the first boat 21a in a high temperature state placed on the ES stage 4B or 4C is extremely effectively cooled by clean air 15 blown from a clean unit 3. Then, for example, when cooled to 150° C. or lower, the first boat 21a is transferred from the ES stage 4B or 4C onto the TR stage 5 by the boat transfer mechanism 30. At this time, it is assumed that the transfer of the unprocessed wafers 7 to the second boat 21b or the third boat 21c on the TR stage 5 has already been completed, and the loading of the second boat 21b or the third boat 21c into the process chamber 101 has also been completed.

By repeating the steps as described above, the substrate processing apparatus 1 according to the present embodiment can form a film on the wafer 7 with high throughput.

### Method for Maintenance of Substrate Processing Apparatus

In the above-described film-forming step, a film is formed on the wafer 7, but actually, a film is formed on other than the wafer 7, for example, the inner wall of the inner tube 104, the boat 21, and the like. When the formed film is thickly deposited, an applied stress increases to cause cracking, which may generate foreign matters (particles) in the process chamber 101. Thus, when the thickness of the film deposited in the process tube 103 reaches a predetermined thickness by repetition of the above-described film-forming step, the substrate processing apparatus 1 according to the present embodiment performs a cleaning step as described below as a maintenance step for maintaining the process tube 103 and the like.

In performing the cleaning step, in the controller section 200, first, a maintenance recipe for cleaning to be performed is read from the memory 207 and deployed in the RAM in the main controller 201. Then, an operation instruction is given from the main controller 201 to each of the controllers 202, 203, 204, and 205, and the cleaning step is performed.

### Cleaning (CLN) Step

The memory 207 stores each of a cumulative value of the thickness of a deposit (accumulated thin film) attached to the process tube 103 (a cumulative film thickness A0 (hereinafter simply referred to as a film thickness A0)), a cumulative value of the thickness of a deposit attached to the first boat 21a (a cumulative film thickness A1 (hereinafter simply referred to as a film thickness A1)), a cumulative value of the thickness of a deposit attached to the second boat 21b (a cumulative film thickness A2 (hereinafter simply referred to as a film thickness A2)), and a cumulative value of the thickness of the deposit attached to the third boat 21c (a cumulative film thickness A3 (hereinafter simply referred to as a film thickness A3)). These cumulative values of the film thickness can be obtained on the basis of a film thickness estimation value analogized from the number of times of use, the use time, and the like in which the process chamber 101 is used in the film-forming step. A film thickness value may be used detected by a film thickness detector (not illustrated) provided in the process chamber 101.

The memory 207 stores a cumulative film thickness threshold value THA (hereinafter simply referred to as a threshold value THA). The threshold value THA is a film thickness before peeling/dropping/cracking occurs due to stress applied in normal processing, and is defined in advance by a user. The definition can be set by being input from the operator 211 by the user. In addition, the memory 207 store a CLN time T0 corresponding to the film thickness A0. The CLN time T0 is set in advance in consideration of a CLN time according to the film thickness A0. The threshold value THA may be acquired from another apparatus connected through a network by the external communicator 213.

Storage processing (storage step) of the film thicknesses A0 to A4 in the memory 207 is executed every time the substrate processing in the process chamber 101 ends, by adding the film thickness of the deposit attached in the substrate processing to the film thickness A0 of the process tube 103 and the cumulative film thickness of the boat subjected to the substrate processing (one of the first boat 21a, the second boat 21b, and the third boat 21c, processed in the process chamber 101). In addition, after execution of CLN processing described later, the film thickness A0 of the process tube 103 and a film thickness A of the boat 21 subjected to the CLN processing are cleared to zero.

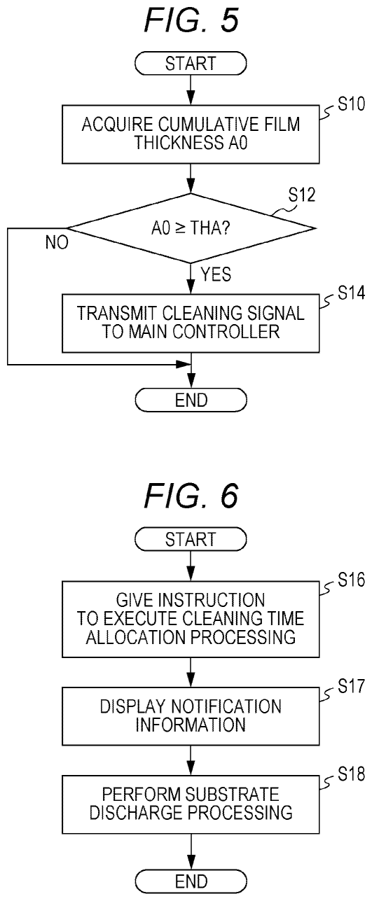

The monitor 220 has a function of monitoring the film thickness A0. Specifically, the film thickness monitoring processing is executed every time the storage processing of the cumulative film thicknesses described above is executed. In the film thickness monitoring processing, as illustrated in FIG. 5, the film thickness A0 of the process chamber 101 is acquired from the memory 207 (step S10), and the acquired film thickness A0 is compared with the threshold value THA (step S12). As a result of the comparison, in a case where the acquired film thickness A0 is greater than or equal to the threshold value THA, in step S14, a CLN signal, which is notification information indicating that it is time to perform CLN, is transmitted to the main controller 201. As a result of the comparison, in a case where the acquired film thickness A0 is less than the threshold value THA, the processing is ended.

When receiving the CLN signal indicating that the film thickness A0 is greater than or equal to the threshold value THA, the main controller 201 determines to start the CLN processing, and requests the calculator 222 to execute CLN time allocation processing as illustrated in FIG. 6 (step S16). The notification information is stored in the memory 207, and display is performed indicating that it is time to perform the CLN and indicating that the CLN processing is to be executed as the notification information on the display 212 (step S17). The display on the display 212 may be an alarm such as lighting of a symbol, or may be notification by voice.

Furthermore, when receiving a signal indicating that the film thickness A0 is greater than or equal to the threshold value THA, the main controller 201 executes discharge processing of the wafers 7 in a case where there is the boat 21 in a state where the wafers 7 are placed thereon (step S18). In a case where the wafers 7 are placed on the first boat 21a, the discharge processing is performed before the CLN processing described later is performed or before step S51 in the CLN processing (before the first boat 21a is loaded into the process chamber 101 and while the temperature of the process chamber 101 is switched to a CLN temperature). In a case where the wafers 7 are placed on the second boat 21b, the discharge processing can be performed during the CLN of the first boat 21a in step S52, and in a case where the wafers 7 are placed on the third boat 21c, the discharge processing can be performed during the CLN of the second boat 21b in step S55.

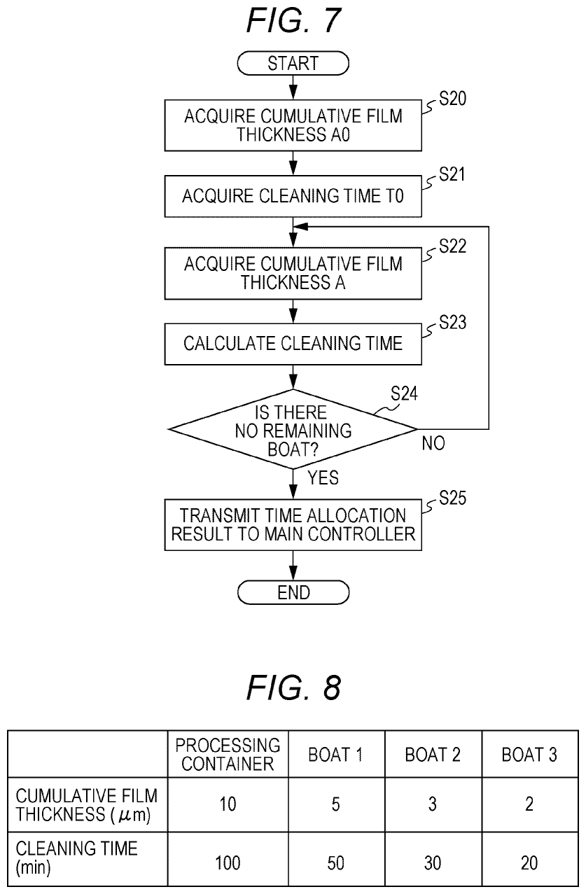

When receiving the request from the main controller 201, the calculator 222 executes the CLN time allocation processing. Specifically, as illustrated in FIG. 7, the film thickness A0 in the process chamber 101 is acquired from the memory 207 in step S20, and the CLN time T0corresponding to the film thickness A0 is acquired from the memory 207 in step S21. Next, in step S22, a cumulative film thickness A (any of A1, A2, and A3: hereinafter, simply referred to as the film thickness A) of one boat 21 is acquired from the memory 207. Then, in step S23, the CLN time (any of T1, T2, and T3) for the boat is calculated. Calculation of the CLN time is performed by allocation of the CLN time T0 corresponding to the acquired film thickness A0 to a time according to the film thickness A of the boat 21. Specifically, the CLN time T0 is multiplied by (the film thickness A)/(the film thickness A0) so as to be proportional to the film thickness A of the boat 21.

In step S24, it is determined whether the calculation of the CLN time has been completed for all the boats 21, and in a case where there is the boat 21 for which the calculation of the CLN time has not been completed, the processing returns to step S22, and the above-described steps S23 and S24 are repeated. In a case where the calculation of the CLN time has been completed for all the boats 21, an allocation result is transmitted to the main controller 201 in step S25, and the CLN time allocation processing is ended.

FIG. 8 shows a table of a specific example of CLN time allocation. It is assumed that the threshold value THA is set to 10 μm. The table shows a case where the film thickness A0 of the process tube 103 (processing container) is 10 μm, the film thickness A1 of the first boat 21a is 5 μm, the film thickness A2 of the second boat 21b is 3 μm, and the film thickness A3 of the third boat 21c is 2 μm, which are stored in the memory 207. Since the boats 21 to be processed using the process chamber 101 are only these boats, the film thickness A0 of the process tube 103 is the sum for these boats 21. The CLN time T0 of the process tube 103 is allocated to these boats 21 so as to be proportional to the film thickness. The CLN time T0 of the process tube 103 is 100 min (set in advance) because the film thickness A0 is 10 μm. Thus, the CLN time T1 of the first boat 21a is 50 min, the CLN time T2 of the second boat 21b is 30 min, and the CLN time T3 of the third boat 21c is 20 min. That is, there is a relationship in which the CLN time T0 is equal to the total CLN time of the CLN time T1, the CLN time T2, and the CLN time T3.

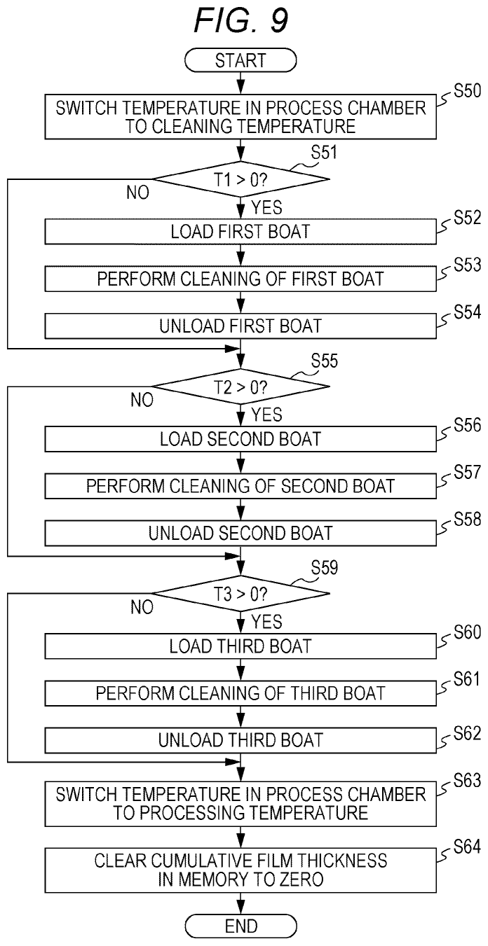

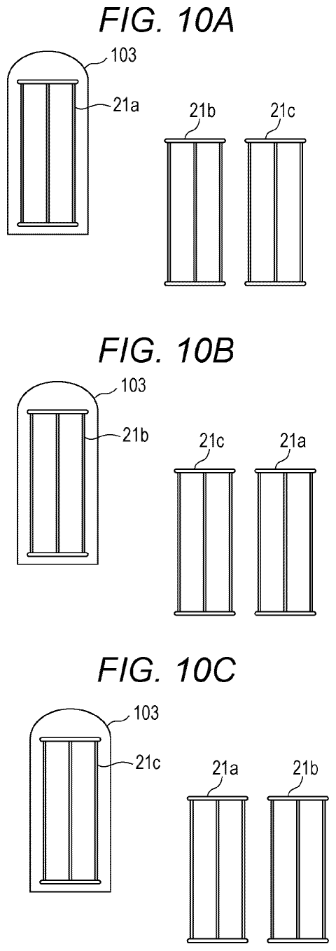

When receiving the allocation result from the calculator 222, the main controller 201 executes the CLN processing. As illustrated in FIG. 9, in the CLN processing, the temperature in the process chamber 101 is switched to the CLN temperature in step S50. In step S51, it is determined whether the CLN time T1 for the first boat 21a is greater than zero, and in a case where the determination is affirmed, the first boat 21a is loaded into the process chamber 101 in step S52, and the CLN of the first boat 21a is performed in step S53 (see FIG. 10A).

In a case where the determination in step S51 is denied, the allocated CLN time T1 for the first boat 21a is zero, and the film thickness A1 is zero, so that the processing in the process chamber 101 is not performed. Thus, steps S52 to S54 are skipped.

In the CLN in step S53, a recipe for the CLN set in advance is executed, such as gas cleaning or purge cleaning. As illustrated in FIG. 10A, the recipe is executed in a state where the first boat 21a is loaded into the process tube 103.

As an example, in the gas cleaning, the CLN gas is supplied into the process chamber 101. The third gas supplied from the third gas supply source 174 into the gas supply pipes 132e and 132f by opening of the valves 162e, 161e, 162f, and 161f is controlled to have a predetermined flow rate by the MFCs 141e and 141f, and then supplied from the nozzles 130a and 130b into the process chamber 101 through the gas supply pipes 132a and 132b.

At this time, the N₂ gas supplied into the process chamber 101 functions as a dilution gas for diluting the F-containing gas that is the CLN gas or a carrier gas for promoting diffusion into the process chamber 101. By controlling the supply flow rate of the N₂ gas, it is possible to control a concentration and a diffusion rate of the F-containing gas.

When passing through the process chamber 101, the F-containing gas comes into contact with the film or the like accumulated in the process chamber 101 or the first boat 21a, and removes the film or the like by a thermochemical reaction. That is, the F-containing gas heated and activated becomes an etching species, and the film or the like accumulated in the process chamber 101 and the first boat 21a are etched and removed.

When the CLN time T1 allocated to the first boat 21a has elapsed, the valves 162e, 161e, 162f, and 161f are closed, and the supply of the F-containing gas into the process chamber 101 is stopped. Then, the valves 162c, 161c, 162d, and 161d are kept open, and the inside of the process chamber 101 is purged by exhausting of the inside of the process chamber 101 while the supply of the N₂ gas into the process chamber 101 is continued. Then, in step S54, the first boat 21a is unloaded from the process chamber 101.

Next, in step S55, it is determined whether the CLN time T2 for the second boat 21b is greater than zero, and in a case where the determination is affirmed, the second boat 21b is loaded into the process chamber 101 in step S56, and the CLN of the second boat 21b is performed in step S57 (see FIG. 10B). The CLN of the second boat 21b is performed similarly to that of the first boat 21a, and regarding the CLN time, the CLN is executed in the CLN time T2 allocated to the second boat 21b. Then, in step S58, the second boat 21b is unloaded from the process chamber 101. In a case where the determination in step S55 is denied, the allocated time T2 is zero and the film thickness A2 is zero for the second boat 21b, so that the processing in the process chamber 101 is not performed. Thus, steps S56 to S58 are skipped.

Next, in step S59, it is determined whether the CLN time T3 for the third boat 21c is greater than zero, and in a case where the determination is affirmed, the third boat 21c is loaded into the process chamber 101 in step S60, and the CLN of the third boat 21c is performed in step S61 (see FIG. 10C). The CLN of the third boat 21c is performed similarly to that of the first boat 21a, and regarding the CLN time, the CLN is executed in the CLN time T3 allocated to the third boat 21c. Then, in step S62, the third boat 21c is unloaded from the process chamber 101.

In a case where the determination in step S59 is denied, the allocated CLN time T3 is zero and the film thickness A3 is zero for the third boat 21c, so that the processing in the process chamber 101 is not performed. Thus, steps S60 to S62 are skipped.

Then, in step S63, the temperature in the process chamber 101 is switched to the processing temperature, and in step S64, the film thickness A0 of the process chamber 101 and the film thickness A of the boat 21 subjected to the CLN processing stored in the memory 207 are cleared to zero, and the CLN processing is ended.

### Effects According to Present Embodiment

According to the present embodiment, one or more effects described below are obtained.

(a) In the present embodiment, the CLN processing is performed on the plurality of boats 21 (first boat 21a, second boat 21b, third boat 21c) at the same timing as the CLN of the process tube 103. Therefore, the time for the CLN processing can be reduced as compared with a case where the CLN of the process tube 103 and the CLN of each boat 21 are separately performed, including the time for adjusting the temperature and atmosphere of the process chamber 101.

(b) In the present embodiment, the CLN time T0 of the process tube 103 is allocated to each boat 21 on the basis of the film thickness A, and each boat 21 is taken in and out of the process chamber 101 in accordance with the allocated CLN time, and the CLN processing is executed. Therefore, residual film thicknesses after one time of CLN processing can be made uniform. In addition, by allocating the CLN time T0 in proportion to the film thickness A, it is possible to set the CLN time according to the film thickness A.

(c) In the present embodiment, the threshold value THA is stored in the memory 207, and the film thickness A0, the film thickness A1, the film thickness A2, and the film thickness A3 are updated and stored every time the substrate processing is performed, and thus, even when the substrate processing apparatus 1 is restarted, information on the film thickness can be maintained. In addition, after the end of the CLN processing, it is possible to maintain the latest cumulative film thickness by clearing these cumulative film thicknesses stored in the memory 207 to zero. The same applies to the notification information.

(d) In the present embodiment, since the threshold value THA can be set by the input from the operator 211, the threshold value THA can be appropriately changed in accordance with the substrate processing conditions and the like.

(e) In the present embodiment, the monitor 220 executes the film thickness monitoring processing every time the substrate processing (film-forming processing) in the process chamber 101 ends. Therefore, the latest film thickness A can be compared with the threshold value THA.

(f) In the present embodiment, in a case where a signal indicating that the cumulative film thickness A0 is greater than or equal to the threshold value THA is received from the monitor 220, the CLN time is calculated. Therefore, the CLN time is calculated only in a case where the CLN is performed, and a CLN calculation time can be reduced.

(g) In the present embodiment, as the notification information, on the display 212, display is performed indicating that it is time to perform the CLN and indicating that the CLN processing is to be executed. Therefore, CLN-related information can be visually presented to the user.

(h) In the present embodiment, in a case where there is the boat 21 in a state where the wafers 7 are placed thereon before the execution of the CLN processing, the discharge processing of the wafers 7 is executed. Since this discharging is performed during a time when the temperature switching of the process chamber 101 is executed or a time when the CLN processing is executed for the other boat 21, the discharging time can be absorbed in the other processing.

(i) In the present embodiment, at the start of the CLN processing, the CLN processing such as loading into the process chamber 101 is skipped for the boat 21 having the film thickness A of zero. Therefore, the time of the entire CLN processing can be shortened.

In a case where the plurality of boats 21 is operated for one processing container, the cumulative film thicknesses in the respective boats 21 may be different from each other. Even in this case, cleaning for efficiently removing the cumulative film can be executed.

The embodiment of the present disclosure has been specifically described above, but the present disclosure is not limited to the embodiment described above, and various modifications can be made without departing from the gist of the present disclosure.

For example, in the above-described embodiment of the present disclosure, as an example, the case has been described where the substrate to be processed is a semiconductor wafer substrate; however, the present disclosure is not limited to the example and can also be suitably applied to a substrate processing apparatus that processes a glass substrate for a liquid crystal display (LCD) device or the like.

In addition, for example, in the above-described embodiment of the present disclosure, the Si-based film formation is taken as an example of the processing performed by the substrate processing apparatus 1, but the present disclosure is not limited thereto. That is, the processing may be processing of forming an oxide film or a nitride film, or processing of forming a film containing metal. The specific content of the substrate processing may be any content, and the present disclosure can be suitably applied not only to the film-forming processing but also to other substrate processing such as annealing processing, oxidizing processing, nitriding processing, diffusion processing, and lithography processing. Furthermore, the present disclosure can also be suitably applied to another substrate processing apparatus, for example, an annealing processing apparatus, an oxidizing processing apparatus, a nitriding processing apparatus, an exposure apparatus, a coating apparatus, a drying apparatus, a heating apparatus, a CVD apparatus using plasma, or the like. Also in these modified examples, effects similar to those of the above-described embodiment can be obtained.

In addition, for example, in the above-described embodiment of the present disclosure, an example has been described of forming a film by using a batch-type substrate processing apparatus that processes a plurality of substrates at a time. The present disclosure is not limited to the above-described embodiment, and can be suitably applied to a case of forming a film by using a single wafer type substrate processing apparatus that processes one or more substrates at a time, for example. In addition, in the above-described embodiment of the present disclosure, an example has been described in which a film is formed by using the substrate processing apparatus including a hot wall type processing furnace. The present disclosure is not limited to the above-described embodiment, and can be suitably applied to a case of forming a film by using a substrate processing apparatus including a cold wall type processing furnace.

Even in cases where such substrate processing apparatuses are used, each type of processing can be performed under the processing procedures and processing conditions similar to those in the above-described embodiment of the present disclosure and modified example, so that effects similar to those in the above-described embodiment and modified example can be obtained.

The above-described embodiment and modified example can be used in combination as appropriate. Processing procedures and processing conditions at this time can be made similar to the processing procedures and processing conditions in the above-described embodiment and modified example, for example.

The entire disclosure of Japanese Patent Application No. 2022-194510 filed on Dec. 5, 2022 is incorporated herein by reference. All documents, patent applications, and technical standards described in the present description are incorporated herein by reference to the same extent as a case where each of the individual documents, the patent applications, and the technical standards is specifically and individually described to be incorporated by reference.

According to the present disclosure, cleaning for efficiently removing a cumulative film can be executed in a substrate processing apparatus that operates a plurality of substrate supports for one processing container.

What is claimed is:

1. A substrate processing apparatus comprising:
a plurality of substrate supports capable of supporting at least one substrate;
a processing container in which the plurality of substrate supports is individually loaded and the substrate supported by the substrate supports is processed;
a gas supplier configured to supply a film forming gas for depositing a film and a cleaning gas removing the deposited film into the processing container;
a memory that stores a cumulative value of a thickness of the deposited film of each of the processing container and two or more of the plurality of substrate supports; and
a controller configured to control the gas supplier to perform a cleaning process of the processing container and the two or more of the plurality of substrate supports,
wherein the cleaning process is performed in a case where the cumulative value of the processing container is greater than or equal to a threshold value defined in advance and,
wherein the cleaning process including:
allocating a cleaning time of the processing container defined in advance for each of the two or more of the plurality of substrate supports on a basis of the cumulative values of each of the plurality of substrate supports;
taking each of the two or more of the plurality of substrate supports into the processing container;
supplying the cleaning gas to remove the deposited film in accordance with cleaning times allocated for each of the two or more of the plurality of substrate supports; and,
taking each of the two or more of the plurality of substrate supports from the processing container.

2. The substrate processing apparatus according to claim 1, wherein the cleaning times of the respective plurality of substrate supports are proportional to the cumulative values of the substrate supports.

3. The substrate processing apparatus according to claim 1, comprising:
a monitor that monitors the cumulative value of the processing container, wherein
the monitor transmits a cleaning signal to the controller in a case where the cumulative value is greater than or equal to the threshold value.

4. The substrate processing apparatus according to claim 3, comprising
an operator capable of setting the threshold value of the processing container, wherein
the monitor compares the threshold value set with the cumulative value of the processing container.

5. The substrate processing apparatus according to claim 3, wherein the monitor determines whether the cumulative value of the processing container is greater than or equal to the threshold value when processing of the substrate ends.

6. The substrate processing apparatus according to claim 1, comprising:
a calculator that calculates the cleaning times of the respective substrate supports, wherein
the controller requests the calculator to calculate the cleaning times of the respective substrate supports in a case where the controller determines to start the cleaning processing.

7. The substrate processing apparatus according to claim 6, wherein the calculator calculates the cleaning times of the respective substrate supports on a basis of the cleaning time of the processing container and the cumulative values of the substrate supports. 8 The substrate processing apparatus according to claim 6, wherein the controller performs execution control of the cleaning processing on a basis of a calculation result by the calculator.

9. The substrate processing apparatus according to claim 1, wherein the controller is configured to be controllable to perform notification of the cumulative value as notification information in a case where the cumulative value of the processing container exceeds the threshold value.

10. The substrate processing apparatus according to claim 9, wherein the memory is capable of storing the notification information.

11. The substrate processing apparatus according to claim 9, comprising a display capable of displaying the notification information, wherein the notification information is displayed on the display.

12. The substrate processing apparatus according to claim 1, wherein in a case where the cleaning processing is to be executed, in a case where the substrate is supported by the substrate support, the controller performs discharging of the substrate before loading the substrate support into the processing container.

13. The substrate processing apparatus according to claim 1, wherein the memory clears the cumulative value stored in the memory after the cleaning processing ends.

14. The substrate processing apparatus according to claim 13, wherein clearing of the cumulative value is performed for the processing container and the substrate supports to which the cleaning processing is performed.

15. The substrate processing apparatus according to claim 1, wherein when the controller executes the cleaning processing, in a case where the cumulative value of the substrate support has not been changed after being cleared, the controller skips the cleaning processing for the substrate support.

16. A method of manufacturing a semiconductor device, comprising:
supporting a substrate on a substrate support capable of supporting at least one substrate;
performing a processing of the substrate, individually loading a plurality of the substrate supports into a processing container and supplying a film forming gas for depositing the film to perform processing of the substrate;
storing a cumulative value of film thickness of the processing container;
storing cumulative values of film thickness of two or more of the plurality of substrate supports; and
performing a cleaning process of the processing container and the two or more of the plurality of substrate supports,
wherein the cleaning process is performed in a case where the cumulative value of the processing container is greater than or equal to a threshold value defined in advance and,
wherein the cleaning process including:
allocating a cleaning time of the processing container defined in advance for each of the two or more of the plurality of substrate supports on a basis of the cumulative values of each of the plurality substrate supports;
taking each of the two or more of the plurality of substrate supports into the processing container;
supplying a cleaning gas to remove the deposited film in accordance with the cleaning times allocated for each of the two or more of the plurality of substrate supports allocated; and,
taking each of the two or more of the plurality of substrate supports from the processing container.

17. A non-transitory computer-readable recording medium storing a program that causes, by a computer, a substrate processing apparatus to perform a process comprising:
supporting a substrate on a substrate support capable of supporting at least one substrate;
performing a processing of the substrate, individually loading a plurality of the substrate supports into a processing container and supplying a film forming gas for depositing the film to perform processing of the substrate;
storing a cumulative value of film thickness of the processing container;
storing cumulative values of film thickness of two or more of the plurality of substrate supports; and
performing a cleaning process of the processing container and the two or more of the plurality of substrate supports,
wherein the cleaning process is performed in a case where the cumulative value of the processing container is greater than or equal to a threshold value defined in advance and,
wherein the cleaning process including:
allocating a cleaning time of the processing container defined in advance for each of the two or more of the plurality of substrate supports on a basis of the cumulative values of each of the plurality of substrate supports;
taking each of the two or more of the plurality of substrate supports into the processing container,
supplying a cleaning gas to remove the deposited film in accordance with the cleaning times allocated for each of the two or more of the plurality of substrate supports allocated; and,
taking each of the two or more of the plurality of substrate supports from the processing container.
